(19) United States
(12) Patent Application Publication
(10) Pub. No.: US 2021/0249804 A1
(43) Pub. Date: Aug. 12, 2021

(54) FLEXIBLE CABLE CONNECTOR FIXING STRUCTURE

(71) Applicant: Energy Full Electronics Co., Ltd, New Taipei City (TW)

(72) Inventor: Hsu-Shen CHIN, New Taipei City (TW)

(73) Assignee: Energy Full Electronics Co., Ltd., New Taipei City (TW)

(21) Appl. No.: 16/841,759

(22) Filed: Apr. 7, 2020

(30) Foreign Application Priority Data
Feb. 10, 2020 (TW) 109201441

(51) Int. Cl. H01R 12/79; H01R 13/58; H05K 3/36; H01R 13/6593

(52) U.S. Cl. CPC H01R 12/79; H01R 13/5812; H01R 13/6335; H01R 13/6593; H05K 2201/10189; H05K 3/361

(57) ABSTRACT

A flexible cable connector fixing structure is disclosed. The flexible cable connector fixing structure comprises a flexible cable. The flexible cable comprises: a plurality of conductors, configured to transfer a power signal or a data signal; and an insulator, covering the plurality of conductors. The flexible cable connector fixing structure further comprises a plurality of terminals, each of the plurality of terminals connected to a corresponding conductor of the plurality of conductors; a first shell, comprising an opening and a plurality of containing cavities, each of the containing cavities is configured to place a corresponding terminal of the plurality of terminals; an isolation part, configured to seal the opening, wherein the plurality of terminals protrude the isolation part; and a cover, covering a part of the plurality of conductors.

### RELATED APPLICATIONS

This application claims the benefit of priority of Taiwan Patent Application No. 109201441 filed on Feb. 10, 2020, the contents of which are incorporated herein by reference in their entirety.

### FIELD AND BACKGROUND OF THE INVENTION

The present invention relates to a flexible cable connector fixing structure, and more particularly, to an easily-installed flexible cable connector fixing structure.

A flex flat cable (FFC) is a new type of data cable. It is manufactured with an insulating material and a very thin flat copper wire with tin plating and is made by a lamination process of an automation equipment. Because of its orderly-arranged wires, high transmission rate, flat structure, small size, good flexibility, the FFC had been widely used in all kinds of electronic devices as a data transmission cable. Especially, the FFC could be used as a connection part between movable parts in high-frequency application because it can be easily bended. As a connection part, the FFC could be inserted into a connector or can be directly soldered on a printed circuit board.

However, because the compactness of the electronic device becomes a big design demand, the size of the cable needs to be smaller as well. This increases the assembling difficulty.

### SUMMARY OF THE INVENTION

One objective of an embodiment of the present invention is to provide a flexible cable connector fixing structure, which has a simple structure and thus solve the above issue of assembling difficulty.

According to an embodiment of the present invention, a flexible cable connector fixing structure is disclosed. The flexible cable connector fixing structure comprises a flexible cable. The flexible cable comprises: a plurality of conductors, configured to transfer a power signal or a data signal; and an insulator, covering the plurality of conductors. The flexible cable connector fixing structure further comprises a plurality of terminals, each of the plurality of terminals connected to a corresponding conductor of the plurality of conductors; a first shell, comprising an opening and a plurality of containing cavities, each of the containing cavities is configured to place a corresponding terminal of the plurality of terminals; an isolation part, configured to seal the opening, wherein the plurality of terminals protrude the isolation part; and a cover, covering a part of the plurality of conductors.

According to one embodiment of the present disclosure, the flexible cable connector fixing structure further comprises a second shell, covering a part of the first shell.

According to one embodiment of the present disclosure, the second shell comprises an upper shell and a lower shell assembling together.

According to one embodiment of the present disclosure, the flexible cable further comprises a metal shielding layer, configured to surround the plurality of conductors.

According to one embodiment of the present disclosure, the metal shield layer is an aluminum foil.

According to one embodiment of the present disclosure, a pattern is coined on a surface of the insulator.

According to one embodiment of the present disclosure, the cover comprise a socket, and the flexible cable is inserted into the socket to allow the plurality of terminals to be connected to the plurality of conductors.

According to one embodiment of the present disclosure, the isolation part comprises a plurality of notches, and each of the terminals extends throughout a corresponding notch of the plurality of notches.

According to one embodiment of the present disclosure, the insulator comprises: a plurality of first insulating jackets, each of the plurality of first insulating jackets covers one of the plurality of conductors; and a second insulating jacket, surrounding the plurality of first insulating jackets.

According to one embodiment of the present disclosure, the plurality of first insulating jackets and the second insulating jacket are manufactured by at least one of polyethylene (PE), polyvinyl chloride (PVC), Thermoplastic Elastomer (TPE), thermoplastic rubber (TPR), Thermoplastic Polyolefin (TPO), Polyurethane (PUR), Polypropylene (PP), Polyolefins (PO), PolyVinyliDene Fluoride (PVDF), Ethylene-chlorotrifluororthylene copolymer (ECTFE), ethylene-tetra-fluoro-ethylene (ETFE), Teflon Fluorinated ethylene propylene (Teflon FEP), Polytetrafluoroethene (PTFE), Teflon and Nylon.

According to an embodiment of the present invention, a flexible cable connector fixing structure is disclosed. The flexible cable connector fixing structure comprises a flexible cable. The flexible cable comprises: a plurality of conductors, configured to transfer a power signal or a data signal; and an insulator, covering the plurality of conductors. The flexible cable connector fixing structure further comprises a plurality of terminals, each of the plurality of terminals connected to a corresponding conductor of the plurality of conductors; a first shell, comprising a plurality of containing cavities, wherein each of the plurality of containing cavities is used to place a corresponding terminal of the plurality of terminals; and a second shell, covering a part of the first shell.

According to one embodiment of the present disclosure, the second shell comprises an upper shell and a lower shell assembling together.

According to one embodiment of the present disclosure, the first shell comprises an opening, the flexible cable connector fixing structure comprises an isolation part and a cover, the isolating part is configured to seal the opening, the plurality of terminals protrude the isolation part, the cover covers a part of the plurality of conductors, and the second shell covers the cover.

According to one embodiment of the present disclosure, the flexible cable further comprises a metal shielding layer, configured to surround the plurality of conductors.

According to one embodiment of the present disclosure, the metal shield layer is an aluminum foil.

According to one embodiment of the present disclosure, a pattern is coined on a surface of the insulator.

According to one embodiment of the present disclosure, the isolation part comprises a plurality of notches, each of the plurality of terminals extends throughout a corresponding notch of the plurality of notches.

According to one embodiment of the present disclosure, the insulator comprises: a plurality of first insulating jackets, each of the plurality of first insulating jackets covers one of the plurality of conductors; and a second insulating jacket, surrounding the plurality of first insulating jackets.

According to one embodiment of the present disclosure, the plurality of first insulating jackets and the second insulating jacket are manufactured by at least one of polyethylene (PE), polyvinyl chloride (PVC), Thermoplastic Elastomer (TPE), thermoplastic rubber (TPR), Thermoplastic Polyolefin (TPO), Polyurethane (PUR), Polypropylene (PP), Polyolefins (PO), PolyVinyliDene Fluoride (PVDF), Ethylene-chlorotrifluororthylene copolymer (ECTFE), ethylene-tetra-fluoro-ethylene (ETFE), Teflon Fluorinated ethylene propylene (Teflon FEP), Polytetrafluoroethene (PTFE), Teflon and Nylon.

In contrast to the conventional art, the flexible cable connector fixing structure of an embodiment has a simple structure and thus is easy to be installed in a compacted electronic device.

### BRIEF DESCRIPTION OF THE SEVERAL VIEWS OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 and FIG. 2 depict explosion drawings of a flexible cable connector fixing structure from opposite viewing angles according to a first embodiment of the present invention.

FIG. 3 is a diagram of the assembled structure of the terminals, the isolation parts, and the flexible cable of FIG. 1.

FIG. 4 is a diagram of a flexible cable connector fixing structure according to a first embodiment of the present invention.

FIG. 5 is a diagram of a flexible cable according to an embodiment of the present invention.

FIG. 6 is a diagram of a flexible cable according to another embodiment of the present invention.

FIG. 7 and FIG. 8 depict explosion drawings of a flexible cable connector fixing structure from opposite viewing angles according to a second embodiment of the present invention.

FIG. 9 is a diagram of the assembled structure of the terminals, the isolation part, the cover and the flexible cable of FIG. 7.

FIG. 10 is a diagram of a flexible cable connector fixing structure according to the second embodiment of the present invention.

FIG. 11 and FIG. 12 depict explosion drawings of a flexible cable connector fixing structure from opposite viewing angles according to a third embodiment of the present invention.

FIG. 13 is a diagram of the assembled structure of the terminals, the isolation part, the cover and the flexible cable of FIG. 11.

FIG. 14 is a diagram of a flexible cable connector fixing structure according to the third embodiment of the present invention.

### DESCRIPTION OF SPECIFIC EMBODIMENTS OF THE INVENTION

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

All of the terminologies containing one or more technical or scientific terminologies have the same meanings that persons skilled in the art understand ordinarily unless they are not defined otherwise. For example, “upper” or “lower” of a first characteristic and a second characteristic may include a direct touch between the first and second characteristics. The first and second characteristics are not directly touched; instead, the first and second characteristics are touched via other characteristics between the first and second characteristics. Besides, the first characteristic arranged on/above/over the second characteristic implies that the first characteristic arranged right above/obliquely above or merely means that the level of the first characteristic is higher than the level of the second characteristic. The first characteristic arranged under/below/beneath the second characteristic implies that the first characteristic arranged right under/obliquely under or merely means that the level of the first characteristic is lower than the level of the second characteristic.

Different methods or examples are introduced to elaborate different structures in the embodiments of the present disclosure. To simplify the method, only specific components and devices are elaborated by the present disclosure. These embodiments are truly exemplary instead of limiting the present disclosure. Identical numbers and/or letters for reference are used repeatedly in different examples for simplification and clearance. It does not imply that the relations between the methods and/or arrangement. The methods proposed by the present disclosure provide a variety of examples with a variety of processes and materials. However, persons skilled in the art understand ordinarily that the application of other processes and/or the use of other kinds of materials are possible.

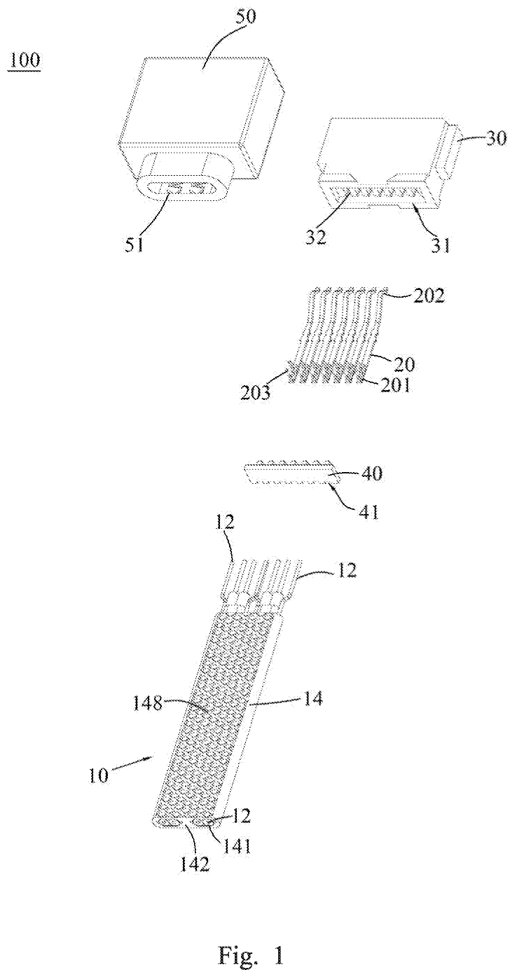

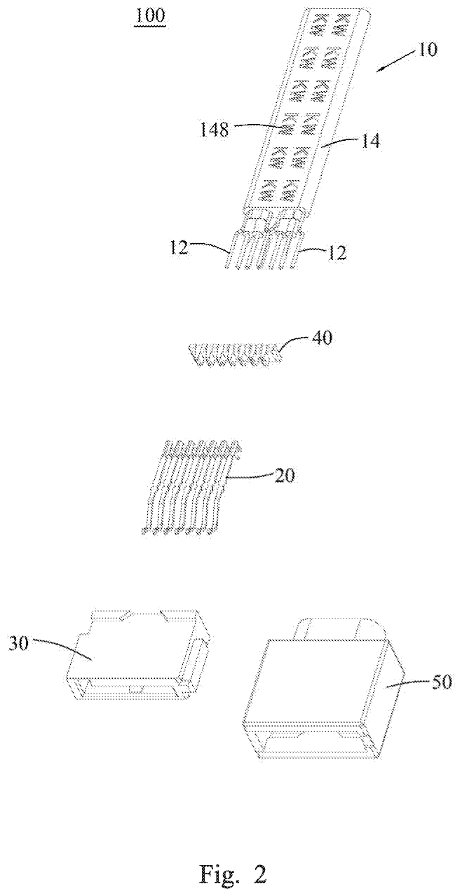

Please refer to FIG. 1 and FIG. 2. FIG. 1 and FIG. 2 depict explosion drawings of a flexible cable connector fixing structure 100 from opposite viewing angles according to a first embodiment of the present invention. The flexible cable connector fixing structure 100 could be inserted into a connector. The connector could be a connector complying with HDMI/USB3.0/USB3.1/Display Port/SATA, having a data rate larger than 1 Gb/s. The flexible cable connector fixing structure 100 comprises a flexible cable 10, a plurality of terminals 20, a first shell 30, an isolation part 40 and a cover 50. The flexible cable 10 comprises a plurality of conductors 12 and an insulator 14. The plurality of conductors 12 are arranged in parallel for transmitting a power signal or a data signal. Each of the terminals 20 is connected to a corresponding conductor 12. The first shell 30 comprises an opening 31 and a plurality of containing cavities 32. Each of the containing cavities 32 is used to place a corresponding terminal 20. The isolation part 40 is used to seal the opening 31. The cover 50 covers a part of the conductors 12.

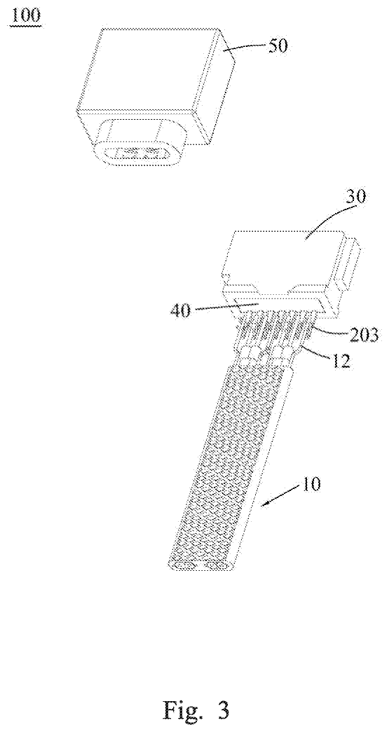

Please refer to FIG. 1, FIG. 2 and FIG. 3. FIG. 3 is a diagram of the assembled structure of the terminals, the isolation parts, and the flexible cable of FIG. 1. The cross-section of the conductor 12 is in a round shape. The surfaces of two sides of the insulator 14 have a coined pattern 148. The conductors 12 of the flexible cable 10 protrude the insulator 14.

The isolation part 40 comprises a plurality of notches 41. When the terminals 20 are inserted into the containing cavities 32 of the first shell 30 and the isolation part 40 seals the opening 31, each of the terminals 20 extends throughout the notch 41 such that the terminals 20 could touch the conductors 12.

The terminal 20 comprise a connecting end 201 and a contacting end 202. The connecting end 201 has a crimping part. The extension direction of the crimping part 203 is vertical to the extending direction of the conductor 12. When the terminal 20 is connected to the conductor 12, the crimping part 203 closely touches the conductor 12. The contacting end 202 could be a protruded structure of a curved shape.

Preferably, the outer surface of the insulator 14 has a coined pattern 148. The coined pattern 148 could be a pattern of multiple parallel lines, multiple curves, or multiple orderly-arranged rounds, ovals, triangles, squares, diamonds, or hexagons. Or, the coined pattern 148 could be a disorderly-arranged pattern, such as consecutive bumps. In this embodiment, the surface area of the flexible cable 10 could be increased without increasing its width. Thus, the heat dissipation capability of the flexible cable is raised and thus the current withstanding capability is also raised. Therefore, the flexible cable 10 could effectively shrink its size and thus solve the above-mentioned issue. The coined pattern 148 could be coined on the outer surface of the insulator 14 by an automation coining equipment.

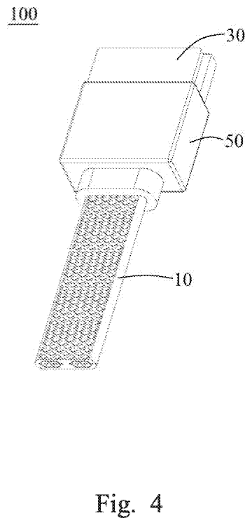

Please refer to FIG. 4, which is a diagram of a flexible cable connector fixing structure 100 according to a first embodiment of the present invention. The cover 50 covers a part of the first shell 30, a part of the insulator 14 of the flexible cable 10, the connecting end 201 of the terminal and a plurality of exposed conductors 12. The cover 50 comprises a socket 51. The flexible cable 10 is inserted into the socket 51 to allow the plurality of terminals 20 to be connected to the plurality of conductors 12. The cover 50 could be formed on the conductor 12 in an insert molding process such that the cover 50 could completely cover the conductors 12.

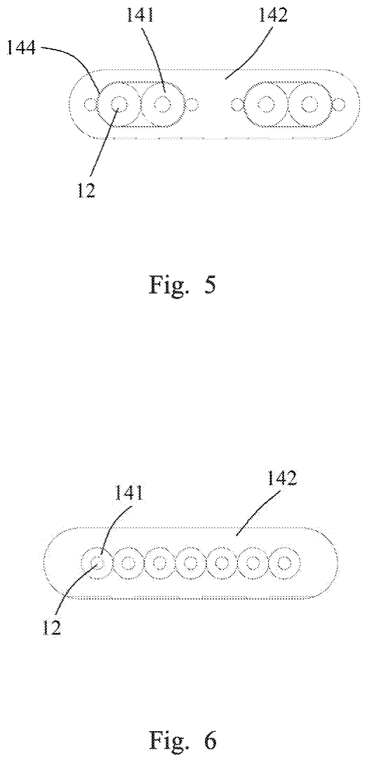

Please refer to FIG. 5, which is a diagram of a flexible cable 10 according to an embodiment of the present invention. The insulator 14 of the flexible cable 10 comprise a metal shielding layer 144, a plurality of first insulating jacket 141 and a second insulating jacket 142. The plurality of conductors 12 are arranged in parallel and the cross-section of the conductor 12 is a round. Each of the first insulating jackets 141 covers one of the conductors 12. The second insulating jacket 142 surrounds the plurality of insulating jackets 141. The outer surfaces at two sides of the second insulating jackets 142 have a coined pattern 148. The plurality of conductors 12 of the flexible cable 10 protrude the first insulating jackets 141 and the second insulating jacket 142. The metal shielding layer 144 covers the first insulating jackets 141 and locates between the first insulating jackets 141 and the second insulating jacket 142 to form a metal shielding effect. This could reduce the interference generated by neighboring conductors 12 during the high-speed signal transmission. Preferably, the metal shielding layer 144 could be an aluminum coil.

Please refer to FIG. 6, which is a diagram of a flexible cable 10 according to another embodiment of the present invention. The insulator 14 of the flexible cable 10 comprises a plurality of first insulating jackets 141 and a second insulating jacket 142. The plurality of conductors 12 are arranged in parallel. The cross-section of the conductor 12 is a round. Each of the first insulating jackets 141 covers one of the conductors 12. The second insulating jacket 142 surrounds the plurality of the first insulating jackets 141. The outer surfaces on both sides of the second insulating jacket 142 have a coined pattern 148. The plurality of conductors 12 of the flexible cable 10 protrude the first insulating jackets 141 and the second insulating jacket 142.

The first insulating jackets 141 and the second insulating jacket 142 are respectively manufactured by at least one of polyethylene (PE), polyvinyl chloride (PVC), Thermoplastic Elastomer (TPE), thermoplastic rubber (TPR), Thermoplastic Polyolefin (TPO), Polyurethane (PUR), Polypropylene (PP), Polyolefins (PO), PolyVinyliDene Fluoride (PVDF), Ethylene-chlorotrifluororthylene copolymer (ECTFE), ethylene-tetra-fluoro-ethylene (ETFE), Teflon Fluorinated ethylene propylene (Teflon FEP), Polytetrafluoroethene (PTFE), Teflon and Nylon.

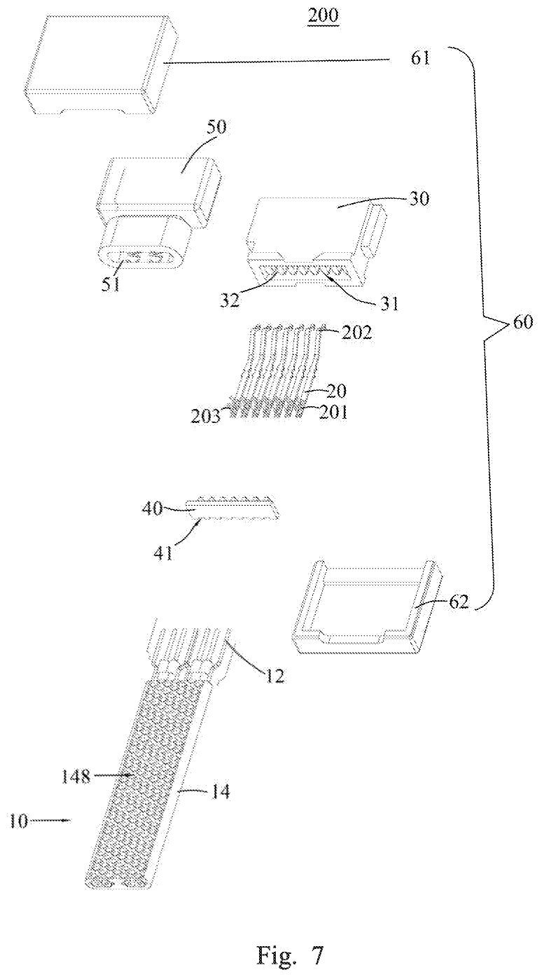

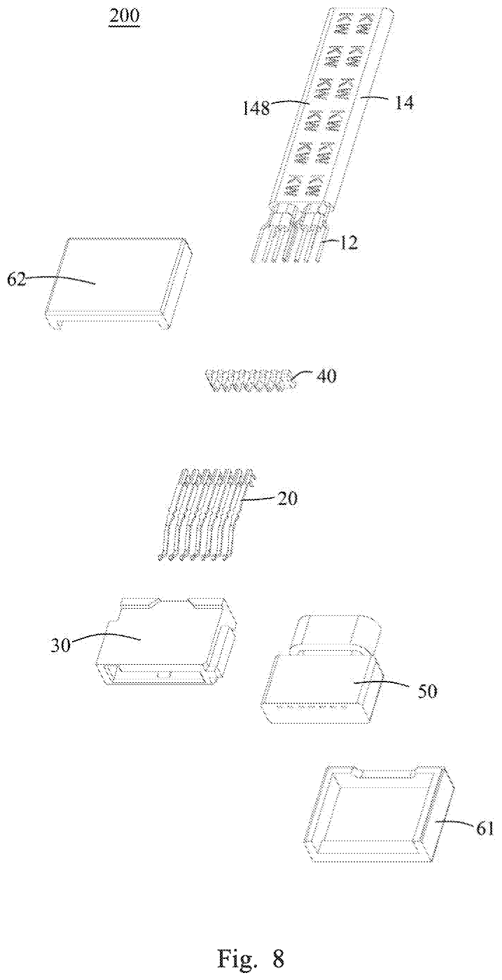

Please refer to FIG. 7 and FIG. 8. FIG. 7 and FIG. 8 depict explosion drawings of a flexible cable connector fixing structure 200 from opposite viewing angles according to a second embodiment of the present invention. The flexible cable connector fixing structure 200 could be inserted into a connector. The connector could be a connect complying with HDMI/USB3.0/USB3.1/Display Port/SATA, having a data rate larger than 1 Gb/s. The flexible cable connector fixing structure 200 comprises a flexible cable 10, a plurality of terminals 20, a first shell 30, an isolation part 40, a cover 50, and a second shell 60. The second shell 60 comprises a top shell 61 a bottom shell 62, which are assembled together. The flexible cable 10 comprises a plurality of conductors 12 and an insulator 14. The plurality of conductors 12 are arranged in parallel for transmitting a power signal or a data signal. Each of the terminals 20 is connected to a corresponding conductor 12. The first shell 30 comprises an opening 31 and a plurality of containing cavities 32. Each of the containing cavities 32 is used to place a corresponding terminal 20. The isolation part 40 is used to seal the opening 31. The cover 50 covers a part of the conductors 12.

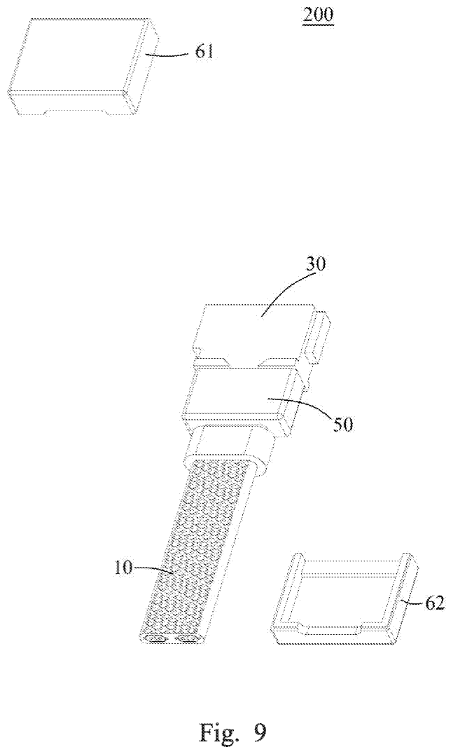

Please refer to FIG. 7, FIG. 8 and FIG. 9. FIG. 9 is a diagram of the assembled structure of the terminals 20, the isolation part 40, the cover 50 and the flexible cable 10 of FIG. 7. The cross-section of the conductors 12 is a round. The surfaces of two sides of the insulator 14 have a coined pattern 148. The conductors 12 of the flexible cable 10 protrude the insulator 14. The isolation part 40 comprises a plurality of notches 41. When the terminals 20 are inserted into the containing cavities 32 of the first shell 30 and the isolation part 40 seals the opening 31, each of the terminals 20 extends throughout the notch 41 such that the terminals 20 could touch the conductors 12. The terminal 20 comprise a connecting end 201 and a contacting end 202. The connecting end 201 has a crimping part. The extension direction of the crimping part 203 is vertical to the extending direction of the conductor 12. When the terminal 20 is connected to the conductor 12, the crimping part 203 closely touches the conductor 12. The contacting end 202 could be a protruded structure of a curved shape.

Preferably, the outer surface of the insulator 14 has a coined pattern 148. The coined pattern 148 could be a pattern of multiple parallel lines, multiple curves, or multiple orderly-arranged rounds, ovals, triangles, squares, diamonds, or hexagons. Or, the coined pattern 148 could be a disorderly-arranged pattern, such as consecutive bumps. In this embodiment, the surface area of the flexible cable 10 could be increased without increasing its width. Thus, the heat dissipation capability of the flexible cable is raised and thus the current withstanding capability is also raised. Therefore, the flexible cable 10 could effectively shrink its size and thus solve the above-mentioned issue. The coined pattern 148 could be coined on the outer surface of the insulator 14 by an automation coining equipment.

The cover 50 covers a part of the first shell 30, a part of the insulator 14 of the flexible cable 10, the connecting end 201 of the terminal and a plurality of exposed conductors 12. The cover 50 comprises a socket 51. The flexible cable 10 is inserted into the socket 51 to allow the plurality of terminals 20 to be connected to the plurality of conductors 12. The cover 50 could be formed on the conductor 12 in an insert molding process such that the cover 50 could completely cover the conductors 12.

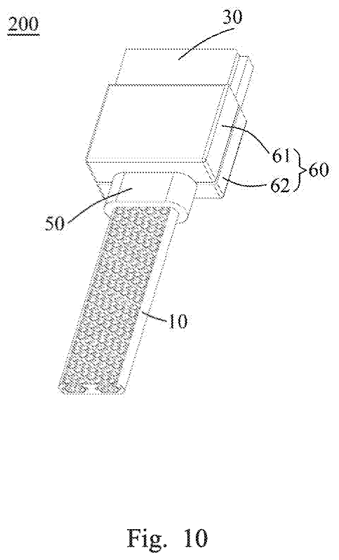

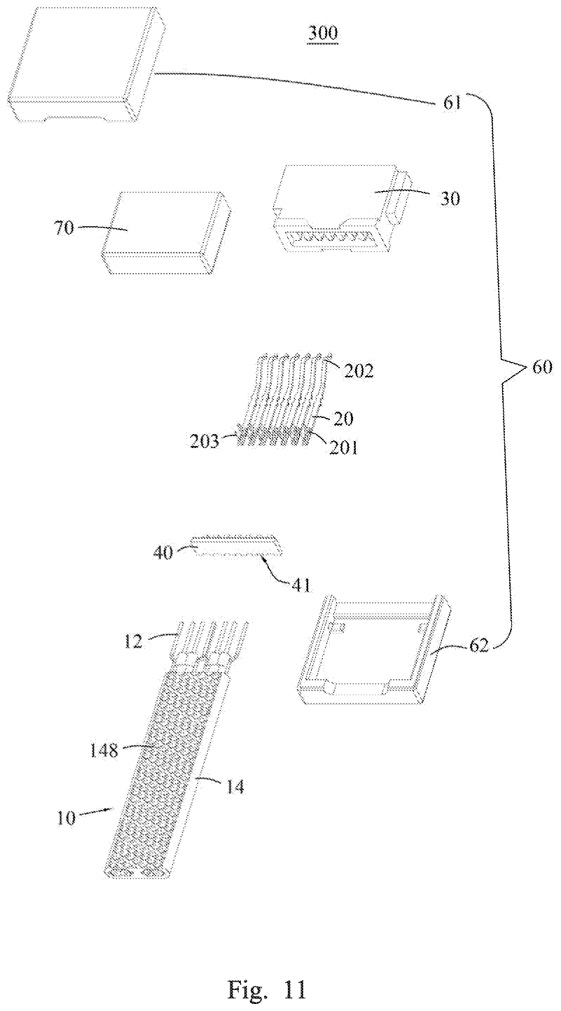

Please refer to FIG. 10. FIG. 10 is a diagram of a flexible cable connector fixing structure according to the second embodiment of the present invention. The top shell 61 and the bottom shell 62 are assembled together to form the second shell 60 such that a part of the cover 50 is covered by the second shell 60. The second shell 60 could improve the protection of the cover 50.

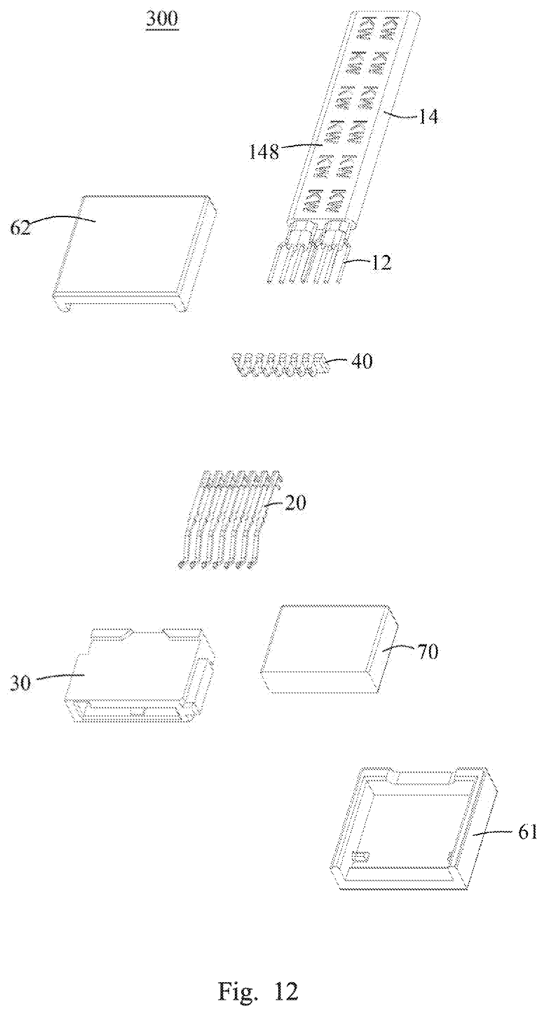

Please refer to FIG. 11 and FIG. 12. FIG. 11 and FIG. 12 depict explosion drawings of a flexible cable connector fixing structure 300 from opposite viewing angles according to a third embodiment of the present invention. The flexible cable connector fixing structure 300 could be inserted into a connector. The connector could be a connect complying with HDMI/USB3.0/USB3.1/Display Port/SATA, having a data rate larger than 1 Gb/s. The flexible cable connector fixing structure 300 comprises a flexible cable 10, a plurality of terminals 20, a first shell 30, an isolation part 40, a cover 70, and a second shell 60. The second shell 60 comprises a top shell 61 a bottom shell 62, which are assembled together. The flexible cable 10 comprises a plurality of conductors 12 and an insulator 14. The plurality of conductors 12 are arranged in parallel for transmitting a power signal or a data signal. Each of the terminals 20 is connected to a corresponding conductor 12. The first shell 30 comprises an opening 31 and a plurality of containing cavities 32. Each of the containing cavities 32 is used to place a corresponding terminal 20. The isolation part 40 is used to seal the opening 31. The cover 70 covers a part of the conductors 12.

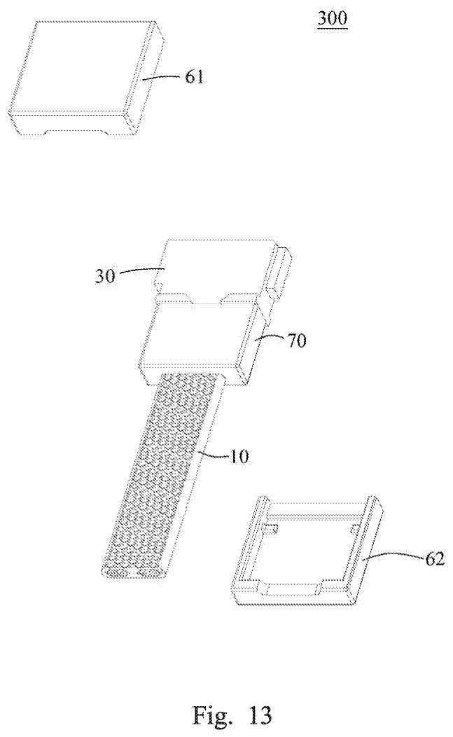

Please refer to FIG. 11, FIG. 12 and FIG. 13. FIG. 13 is a diagram of the assembled structure of the terminals 20, the isolation part 40, the cover 70 and the flexible cable 10 of FIG. 11. The cross-section of the conductors 12 is a round. The surfaces of two sides of the insulator 14 have a coined pattern 148. The conductors 12 of the flexible cable 10 protrude the insulator 14. The isolation part 40 comprises a plurality of notches 41. When the terminals 20 are inserted into the containing cavities 32 of the first shell 30 and the isolation part 40 seals the opening 31, each of the terminals 20 extends throughout the notch 41 such that the terminals 20 could touch the conductors 12. The terminal 20 comprise a connecting end 201 and a contacting end 202. The connecting end 201 has a crimping part. The extension direction of the crimping part 203 is vertical to the extending direction of the conductor 12. When the terminal 20 is connected to the conductor 12, the crimping part 203 closely touches the conductor 12. The contacting end 202 could be a protruded structure of a curved shape.

Preferably, the outer surface of the insulator 14 has a coined pattern 148. The coined pattern 148 could be a pattern of multiple parallel lines, multiple curves, or multiple orderly-arranged rounds, ovals, triangles, squares, diamonds, or hexagons. Or, the coined pattern 148 could be a disorderly-arranged pattern, such as consecutive bumps. In this embodiment, the surface area of the flexible cable 10 could be increased without increasing its width. Thus, the heat dissipation capability of the flexible cable is raised and thus the current withstanding capability is also raised. Therefore, the flexible cable 10 could effectively shrink its size and thus solve the above-mentioned issue. The coined pattern 148 could be coined on the outer surface of the insulator 14 by an automation coining equipment.

The cover 70 covers a part of the first shell 30, a part of the insulator 14 of the flexible cable 10, the connecting end 201 of the terminal and a plurality of exposed conductors 12. The flexible cable 10 is inserted into the cover 70 to allow the plurality of terminals 20 to be connected to the plurality of conductors 12. The cover 70 could be formed on the conductor 12 in an insert molding process such that the cover 70 could completely cover the conductors 12.

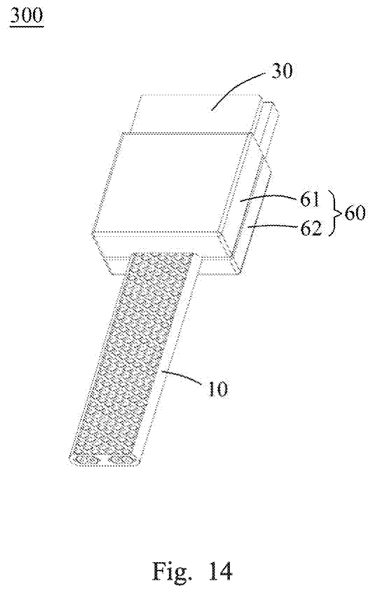

Please refer to FIG. 14. FIG. 14 is a diagram of a flexible cable connector fixing structure 300 according to a third embodiment of the present invention. The top shell 61 and the bottom shell 62 are assembled together to form the second shell 60 such that a part of the cover 70 is covered by the second shell 60. The second shell 60 could improve the protection of the cover 70.

It could be understood by one having ordinary skills in the art that the flexible cable 10 of the flexible cable connector fixing structure 200/300 could adopt the structure shown in FIG. 5 or FIG. 6. These changes fall within the scope of the present invention.

In contrast to the conventional art, the flexible cable connector fixing structure of an embodiment has a simple structure and thus is easy to be installed in a compacted electronic device.

Above are embodiments of the present invention, which does not limit the scope of the present invention. Any modifications, equivalent replacements or improvements within the spirit and principles of the embodiment described above should be covered by the protected scope of the invention.

What is claimed is:

1. A flexible cable connector fixing structure, comprising:
a flexible cable, comprising:
a plurality of conductors, configured to transfer a power signal or a data signal; and
an insulator, covering the plurality of conductors;
a plurality of terminals, each of the plurality of terminals connected to a corresponding conductor of the plurality of conductors;
a first shell, comprising an opening and a plurality of containing cavities, each of the containing cavities is configured to place a corresponding terminal of the plurality of terminals;
an isolation part, configured to seal the opening, wherein the plurality of terminals protrude the isolation part; and
a cover, covering a part of the plurality of conductors.

2. The flexible cable connector fixing structure of claim 1, further comprising:
a second shell, covering a part of the first shell.

3. The flexible cable connector fixing structure of claim 2, wherein the second shell comprises an upper shell and a lower shell assembling together.

4. The flexible cable connector fixing structure of claim 1, wherein the flexible cable further comprises a metal shielding layer, configured to surround the plurality of conductors.

5. The flexible cable connector fixing structure of claim 4, wherein the metal shield layer is an aluminum foil.

6. The flexible cable connector fixing structure of claim 1, wherein a pattern is coined on a surface of the insulator.

7. The flexible cable connector fixing structure of claim 4, wherein the cover comprise a socket, and the flexible cable is inserted into the socket to allow the plurality of terminals to be connected to the plurality of conductors.

8. The flexible cable connector fixing structure of claim 1, wherein the isolation part comprises a plurality of notches, and each of the terminals extends throughout a corresponding notch of the plurality of notches.

9. The flexible cable connector fixing structure of claim 1, wherein the insulator comprises:
a plurality of first insulating jackets, each of the plurality of first insulating jackets covers one of the plurality of conductors; and
a second insulating jacket, surrounding the plurality of first insulating jackets.

10. The flexible cable connector fixing structure of claim 9, wherein the plurality of first insulating jackets and the second insulating jacket are manufactured by at least one of polyethylene (PE), polyvinyl chloride (PVC), Thermoplastic Elastomer (TPE), thermoplastic rubber (TPR), Thermoplastic Polyolefin (TPO), Polyurethane (PUR), Polypropylene (PP), Polyolefins (PO), PolyVinyliDene Fluoride (PVDF), Ethylene-chlorotrifluororthylene copolymer (ECTFE), ethylene-tetra-fluoro-ethylene (ETFE), Teflon Fluorinated ethylene propylene (Teflon FEP), Polytetrafluoroethene (PTFE), Teflon and Nylon.

11. A flexible cable connector fixing structure, comprising:
a flexible cable, comprising:
a plurality of conductors, configured to transfer a power signal or a data signal; and
an insulator, covering the plurality of conductors;
a plurality of terminals, each of the plurality of terminals connected to a corresponding conductor of the plurality of conductors;
a first shell, comprising a plurality of containing cavities, wherein each of the plurality of containing cavities is used to place a corresponding terminal of the plurality of terminals; and
a second shell, covering a part of the first shell.

12. The flexible cable connector fixing structure of claim 11, wherein the second shell comprises an upper shell and a lower shell assembling together.

13. The flexible cable connector fixing structure of claim 11, wherein the first shell comprises an opening, the flexible cable connector fixing structure comprises an isolation part and a cover, the isolating part is configured to seal the opening, the plurality of terminals protrude the isolation part, the cover covers a part of the plurality of conductors, and the second shell covers the cover.

14. The flexible cable connector fixing structure of claim 11, wherein the flexible cable further comprises a metal shielding layer, configured to surround the plurality of conductors.

15. The flexible cable connector fixing structure of claim 14, wherein the metal shield layer is an aluminum foil.

16. The flexible cable connector fixing structure of claim 11, wherein a pattern is coined on a surface of the insulator.

17. The flexible cable connector fixing structure of claim 13, wherein the isolation part comprises a plurality of notches, each of the plurality of terminals extends throughout a corresponding notch of the plurality of notches.

18. The flexible cable connector fixing structure of claim 11, wherein the insulator comprises:
a plurality of first insulating jackets, each of the plurality of first insulating jackets covers one of the plurality of conductors; and
a second insulating jacket, surrounding the plurality of first insulating jackets.

19. The flexible cable connector fixing structure of claim 18, wherein the plurality of first insulating jackets and the second insulating jacket are manufactured by at least one of polyethylene (PE), polyvinyl chloride (PVC), Thermoplastic Elastomer (TPE), thermoplastic rubber (TPR), Thermoplastic Polyolefin (TPO), Polyurethane (PUR), Polypropylene (PP), Polyolefins (PO), PolyVinyliDene Fluoride (PVDF), Ethylene-chlorotrifluororthylene copolymer (ECTFE), ethylene-tetra-fluoro-ethylene (ETFE), Teflon Fluorinated ethylene propylene (Teflon FEP), Polytetrafluoroethene (PTFE), Teflon and Nylon.
